(19) United States
(12) Patent Application Publication
(10) Pub. No.: US 2022/0367497 A1
(43) Pub. Date: Nov. 17, 2022

(54) INTEGRATED CIRCUIT COMPRISING A NON-VOLATILE MEMORY OF THE EEPROM TYPE AND CORRESPONDING MANUFACTURING METHOD

(71) Applicant: STMicroelectronics (Rousset) SAS, Rousset (FR)

(72) Inventors: Francois TAILLIET, Fuveau (FR); Roberto SIMOLA, Trets (FR); Philippe BOIVIN, Venelles (FR)

(73) Assignee: STMicroelectronics (Rousset) SAS, Rousset (FR)

(21) Appl. No.: 17/734,963

(22) Filed: May 2, 2022

(30) Foreign Application Priority Data
May 11, 2021 (FR) 2104996

(51) Int. Cl. H01L 27/11529; H01L 27/11524

(52) U.S. Cl. CPC H01L 27/11529; H01L 27/11524

(57) ABSTRACT

The integrated circuit of a non-volatile memory of the electrically erasable and programmable type includes memory cells, each memory cell having a state transistor including a gate structure comprising a control gate and a floating gate disposed on a face of a semiconductor well, as well as a source region and a drain region in the semiconductor well. The drain region includes a first capacitive implant region positioned predominantly under the gate structure and a lightly doped region positioned predominantly outside the gate structure. The source region includes a second capacitive implant region positioned predominantly outside the gate structure, the source region not including a lightly doped region.

### BACKGROUND

### Technical Field

Embodiments and implementations concern the field of electrically erasable and programmable non-volatile memories “EEPROM” (acronym for “Electrically Erasable and Programmable Read Only Memory”), made on an integrated circuit and the corresponding manufacturing methods.

### Description of the Related Art

An EEPROM memory is typically composed of a memory plane of memory cells, which are adapted to store data, and a management circuit, in particular adapted to carry out writes and reads in the memory plan.

The EEPROM memory cells typically include a state transistor in series with an access transistor, the state transistor being a floating gate transistor adapted to store a data bit, the access transistor allowing selectively controlling the access to the state transistors belonging to a group of memory cells called memory word.

A constant objective in the field of EEPROM memories is to reduce the surface area of the memory cells. This can typically result in a reduction in the length of the channel of the state transistor, which generates instabilities and reliability problems.

The instabilities are caused in particular by variations between the alignment of a capacitive implant region under the floating gate and the alignment of the gate structure (floating gate and control gate). These variations cause a variable channel length, due to a specific morphology of the channel region of the state transistor.

Indeed, the capacitive implant region is a doped region extending under a tunnel window of the floating gate on the side of the drain region and forms an extension of the drain region. The capacitive implant typically has a more concentrated and shallower doping than the drain region and allows forming a capacitive structure between the drain and the floating gate in order to allow write operations.

Thus, in this morphology, the length of the channel is defined by the source region, on the one hand, the latter being typically self-aligned to the implantation on an edge of the gate structure, and by the capacitive implant region under the gate, on the other hand.

The variations in the length of the channel cause a spread of the threshold values of the productions of state transistors, which penalizes the reading of the cells.

A channel length which is too short resulting from these variations can cause short channel effects and severe degradations by hot carriers during the programming phases.

The short channel effects are conventionally a physical limitation to the shrinkage of memory cells, in the direction of the length of the channel.

FIG. 1 illustrates an example of a solution to the problem of varying the length of the channel, in a sectional view of a memory cell CEL0 including a state transistor TE0 and an access transistor TAO. The memory cell CEL0 is represented in a nominal position 10 and in a position 20 resulting from misalignment.

In the nominal position 10, the channel region 11 is defined between a conventional capacitive implant region 12 on the drain side, and a second capacitive implant 13 on the source side, both from the same implantation step. The source region 14 is aligned on the gate structure SGF10 of state transistor TE0 upon the implantation thereof, and extends to the channel region 11 after diffusion 14d. However, the channel length 11 does not normally depend on the relative alignment between the structure SGF10 defining the source region 14-14d and the capacitive implants 12-13. Indeed, the capacitive implant 13 on the source side is provided to protrude under the structure SGF10 by a measurement 17 sufficient to exceed the extent of the diffusion 14d by a measurement 18.

The position 20 illustrates this configuration, in the case of a misalignment of the position of the gate structure SGF20 by an offset D1 away from the source region relative to the nominal position 10, and a misalignment of the capacitive implant regions 22-23 by an offset D2 approaching the source region 24-24d relative to the nominal position 10. In the case of the position 20, the diffused portion 24d of the source region 24-24d (offset by D1) exceeds by a measurement 25 the capacitive implant region 23 on the source side (offset by D2). Consequently, the channel length 21 is reduced by the measurement 25 relative to the nominal channel length 11.

The solution represented in FIG. 1 allows avoiding this problem by sufficiently increasing the margin offered by the measurement 18, and therefore by increasing the measurement 17, that is to say the size of the portion of the capacitive implant region 13 protruding under the structure SGF10.

However, the channel length 11 cannot be reduced because of the short channel effects, and the measurement 19 between the edge of the structure SGF10 and a metal contact pillar CNT also cannot be reduced because of a risk of short-circuit with the gates SGF10.

Consequently, increasing or setting the measurement 17 decreases the possibilities for reducing the dimensions of the cell CEL0 in the direction of the channel.

### BRIEF SUMMARY

In view of the foregoing, there is a need or desire to propose means allowing reducing the size of the memory cells in the direction of the channel and protecting against the short channel effects in the case of misalignment.

According to one aspect, there is proposed in this regard an integrated circuit comprising a non-volatile memory of the electrically erasable and programmable type including memory cells, each memory cell having a state transistor including a gate structure comprising a control gate and a floating gate disposed on a face of a semiconductor well, as well as a source region and a drain region in the semiconductor well. The drain region including a first capacitive implant region positioned predominantly under the gate structure and a lightly doped region positioned predominantly outside the gate structure. The source region includes a second capacitive implant region positioned predominantly outside the gate structure, and the source region does not include a lightly doped region.

As an indication, the term “a region positioned predominantly under a structure” means that more than 50% of the region is positioned under the structure. In other words, it means that a major portion of the region, that is to say a portion of the region whose size is larger than the size of the rest of the region, is positioned under the structure, and, by complementarity, that a minor portion of the region, that is to say the rest of the region which is not the major portion of the region, is not located under the structure.

Also, the term “a region in a well which is positioned predominantly outside a structure disposed on one face of the well” means that a major portion (more than 50%) of the region is located opposite to the outside the structure, that is to say is not located under the structure, and, by complementarity, that a minor portion of the region, that is to say the rest of the region which is not the major portion of the region, is located under the structure.

In other words, the conventional implantation of the source region 14-14d (FIG. 1) is not carried out, and the source region consists only of the second capacitive implant region. This allows preventing the source region from diffusing inside the channel in the direction of the drain, and thus avoiding a reduction in the channel length caused by misalignment.

Furthermore, the absence of diffusion inside the channel allows considerably reducing the covering of the second capacitive implant region under the gate, while benefiting from the channel length monitored between the first capacitive implant region and the second capacitive implant region.

The reduction in the size of the covering of the second capacitive implant region under the gate affects the total size of a memory cell (in the direction of the length of the channel), offering a reduction in the range of 3% of the total size.

Moreover, the solution according to this aspect does not have any risk related to hot carriers, since the source is typically always at low potential.

According to one embodiment, in a nominal position of the gate structure and the second capacitive implant region, a minor portion of the second capacitive implant region is positioned under the gate structure, said minor portion having the minimum size allowing compensating for a tolerance of variations in the dimensions and alignment of the gate structure, and a tolerance of variations in the dimensions and alignment of the capacitive implant regions.

The term “nominal position” means the position of an embodiment having no misalignment, that is to say also the position provided in the architectural drawings of the integrated circuit. In an embodiment having misalignment, it is possible to identify and measure these misalignments and deduce the nominal position therefrom. For example, if two embodiments have a symmetry such as an offset in one direction relative to one of the embodiments (for example an offset towards the drain), introduces into the symmetrical structure a relative offset in the other direction (for example towards the source), then it is possible to deduce the nominal position by averaging the offsets.

Strictly speaking, such a measurement of misalignment allows deducing the nominal position of the capacitive implant region, after diffusion. After diffusion, the capacitive implant region has a size which is slightly larger than the nominal size considered at the implantation mask and as provided in the architectural drawings of the integrated circuit.

However, due to the shallow depth of the capacitive implant region, the capacitive implant region diffuses very slightly, in particular compared to the diffusion of the conventional lightly doped source and drain regions. Therefore, by simplification, the size of the diffusion of the capacitive implant region can be neglected.

At least some embodiments correspond to the optimal compromise between the absence of risk caused by a misalignment, and the reduction in size of the memory cell.

According to one embodiment, a channel region of the well located under the gate structure, is delimited on either side by the first capacitive implant region and by the second capacitive implant region.

The first capacitive implant region and the second capacitive implant region are typically formed during the same masking and implantation step. Consequently, the length of the channel region is invariable relative to a possible misalignment of this step.

According to one embodiment, the gate structure includes a dielectric layer between the floating gate and the semiconductor well, the dielectric layer having a first thickness and a second thickness less than the first thickness, the channel region being positioned opposite to the first thickness, and the first capacitive implant region being positioned predominantly opposite to the second thickness.

According to one embodiment in which each memory cell further has an access transistor including a gate structure disposed on the face of the semiconductor well, as well as a source region and a drain region in the semiconductor well, the drain region of the access transistor includes a lightly doped region positioned predominantly outside the gate structure of the access transistor, and the source region of the access transistor includes the same lightly doped region as the drain region of the state transistor, positioned predominantly outside the structure gate of the access transistor.

According to another aspect, it is proposed a method for manufacturing a non-volatile memory of the electrically erasable and programmable type of an integrated circuit, comprising a formation of state transistors of memory cells comprising, for each memory cell:
an implantation, in a semiconductor well, of a first capacitive implant region positioned on a drain side of the state transistor and of a second capacitive implant region positioned on a source side of the state transistor;
a formation of a gate structure on a face of the semiconductor well comprising a control gate and a floating gate, positioned such that a major portion of the first capacitive implant region is located under the gate structure and that a major portion of the second capacitive implant region is located outside the gate structure;
a formation of a lightly doped region, comprising a formation of a temporary mask on the semiconductor substrate on the source side of the state transistor, and an implantation of dopants self-aligned on the gate structure on the drain side of the state transistor.

It is thus proposed to prevent the implantation of the lightly doped region in the source region of the state transistor, by means of a mask during this implantation. This allows, as previously expressed, avoiding the risk of reducing the length of the channel while reducing the size of the memory cells.

Furthermore, from the point of view of the cost of implementing the method according to this aspect, the introduction of a mask during the step of implanting the lightly doped region does not introduce an additional step in itself, but a simple modification of a typically already existing mask to carry out the self-aligned implantation in the uncovered portions of this mask.

According to one embodiment, in a nominal position of the positioning of the implantation of the capacitive implant regions and the positioning of the formation of the gate structure, a minor portion of the second capacitive implant region is positioned under the gate structure, said minor portion having the minimum size allowing compensating for a tolerance of variations in the dimensions and alignment of the gate structure, and a tolerance of variations in the dimensions and alignment of the capacitive implant regions.

According to one embodiment, the implantation of the first capacitive implant region and the implantation of the second capacitive implant region delimit on either side a channel region of the well, and the formation of the gate structure is positioned such that the channel region is located under the gate structure.

According to one embodiment, the formation of the gate structure comprises a formation of a dielectric layer between the floating gate and the semiconductor well, comprising a formation of a first thickness of the dielectric layer and a second thickness of the dielectric layer which is less than the first thickness, the formation of the gate structure being positioned such that the channel region is located opposite to the first thickness, and that the first capacitive implant region is positioned predominantly opposite to the second thickness.

According to one embodiment, the method further comprises a formation of access transistors for each memory cell, and:
said formation of the gate structure of the state transistor further comprises a formation of a gate structure of the access transistor;
said formation of the lightly doped region, comprises said implantation of dopants further self-aligned on the gate structure of the access transistor forming a lightly doped region of the drain of the access transistor and a lightly doped region of a source of the access transistor which is common to the lightly doped region of the drain of the state transistor.

### BRIEF DESCRIPTION OF THE SEVERAL VIEWS OF THE DRAWINGS

Other advantages and features of the invention will appear on examining the detailed description of embodiments and implementations, which are in no way limiting, and of the appended drawings, in which:

FIG. 1 previously described, illustrates a problem of the prior art;

FIG. 2 illustrates a sectional view of a memory cell belonging to an integrated circuit of a non-volatile memory of the electrically erasable and programmable type EEPROM;

FIG. 3 illustrates a step for implanting, in a semiconductor well, capacitive implant regions;

FIG. 4 illustrates a final step in the formation of the gate structure of the future state transistor and the gate structure of the future access transistor;

FIG. 5 illustrates a formation of the lightly doped regions; and

FIG. 6 illustrates the result of forming of metal contact pillars, and of diffusing the lightly doped regions which are implanted.

### DETAILED DESCRIPTION

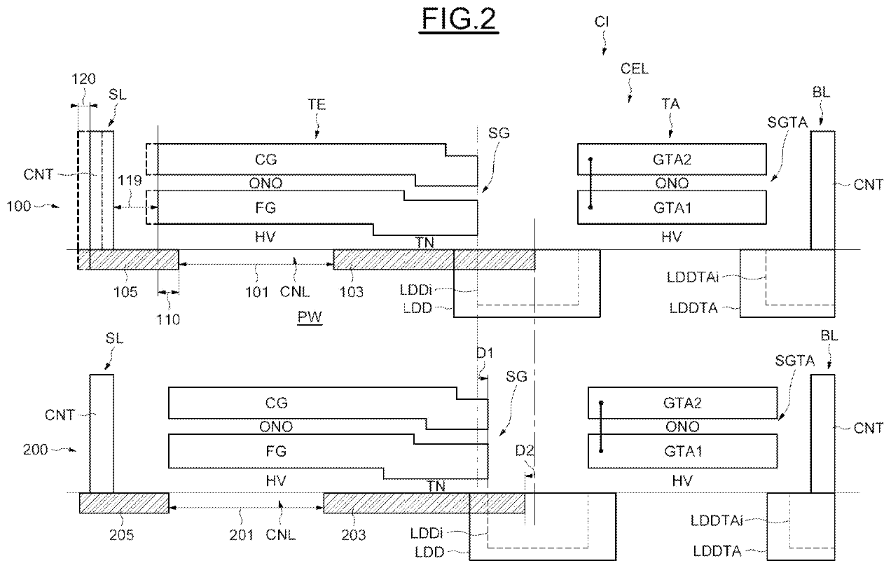

FIG. 2 illustrates a sectional view of a memory cell CEL belonging to an integrated circuit CI of A non-volatile memory of the electrically erasable and programmable type EEPROM. The EEPROM memory typically includes a memory plane provided with memory cells CEL, which can represent more than 50% of the total size of the integrated circuit CI, and a peripheral control circuit.

The memory cell CEL is represented in a nominal position 100 and in an “offset” position 200.

Each memory cell CEL includes a state transistor TE and an access transistor TA in series, made from a semiconductor well PW belonging to a semiconductor substrate of the integrated circuit CI, typically made of P-type doped silicon.

The state transistor TE is adapted to store binary data and comprises in this regard a gate structure SG comprising a control gate CG and a floating gate FG. The floating gate FG is electrically insulated from the control gate by an inter-gate dielectric layer ONO and from the well PW by a dielectric layer HV-TN. The floating gate FG can thus store electric charges in a non-volatile manner. The injection of charges into the floating gate is obtained by the Fowler-Nordheim effect through a dielectric tunnel TN. The control gate CG constitutes a terminal of the state transistor TE allowing control by field effect the conduction of a channel region CNL in the well PW, when a control voltage greater than the threshold value of the state transistor TE is applied thereto. The charges which are stored or not in the floating gate FG screen or not the field effect of the control voltage, which results in a change in the threshold value of the state transistor TE. It is this change in the threshold value which is detected to read the data stored in the memory cell CEL.

The access transistor TA is coupled in series between the drain LDD of the state transistor TE and a bit line BL, used in particular to selectively access the memory cell CEL, in writing and in reading.

The source region LDD of the access transistor TA is a lightly doped region shared with the drain region of the state transistor TE. The drain region LDDTA of the access transistor TA is coupled to the bit line BL via a metal contact pillar CNT.

The gate structure SGTA of the access transistor TA is of the single gate type, but may comprise, for manufacturing method reasons, an inner conductive gate GTA1 separated from the well PW by a dielectric layer HV, and separated from an upper conductive gate GTA2 by an inter-gate dielectric layer ONO. The two conductive gates GTA1, GTA2 are electrically connected for a single gate transistor function.

The lightly doped regions LDD, LDDTA are implanted in self-alignment on the gate structure SG of the state transistor TE and on the gate structure SGTA of the access transistor TA (see below in relation to FIG. 5).

Consequently, the lightly doped regions LDD, LDDTA are initially located in implantation areas LDDi, LDDTAi outside the gate structures SG, SGTA and delimited perpendicular to the borders of the gate structures SG, SGTA. After diffusion, the lightly doped regions LDD, LDDTA, that is to say the source and drain regions of the access transistor TA as well as the drain region of the state transistor TE, are mainly located outside the gate structure of the state transistor SG and outside the gate structure of the access transistor SGTA, and include diffused portions, located under the gate structures SG, SGTA.

The lightly doped regions LDD, LDDTA, are usually called “Lightly Doped Drain,” regardless of the source or drain function of the target region. The use of such lightly doped regions LDD, LDDTA allows in particular ensuring an avalanche voltage, in the junctions PN formed with the well PW, which is high enough to withstand high write voltages, in the range of 12 to 14 V (volts), and thus limiting aging by hot carriers.

Moreover, the state transistor TE further includes a first capacitive implant region 103 extending under the gate structure SG from the side of the drain LDD. One can consider that the first capacitive implant region 103 constitutes an extension of the drain region LDD of the state transistor, forming a capacitive structure with the floating gate FG at a tunnel window TN.

The tunnel window is formed in the dielectric layer HV-TN separating the floating gate FG and the well PW. In the tunnel window TN, the dielectric layer has a second thickness TN, less than a first thickness HV of the rest of the dielectric layer.

The dielectric material is, for example, silicon oxide, with the first thickness HV in the range of 22 nm (nanometers) and the second thickness TN in the range of 7 to 9 nm.

Thus, the first capacitive implant region 103 is positioned predominantly opposite to the second thickness TN.

On the other hand, the first capacitive implant region 103 allows delimiting one end of the length 101 of the channel region CNL of the state transistor TE. A second capacitive implant region 105 allows delimiting the other end of length 101 of the channel region CNL of the state transistor TE.

Thus, the channel region CNL located in the well PW under the gate structure SG, is delimited on either side by the first capacitive implant region 103 and by the second capacitive implant region 105.

More particularly, the channel region CNL is positioned opposite to the first thickness HV of the dielectric layer located between the well PW and the floating gate FG.

Also, the second capacitive implant region 105 is positioned predominantly outside the gate structure SG, and exclusively constitutes the source region of the state transistor TE. In particular, the source region does not include a lightly doped region.

A metal contact pillar CNT allows coupling the source region of the state transistor TE, that is to say the second capacitive implant region 105, with a source line SL.

Typically, the voltage of the source line SL never exceeds a relatively low potential, for example in the range of 5 or 6V.

Consequently, the junction PN between the second capacitive implant region 103 and the well PW is not likely to be degraded by hot carriers, despite an avalanche voltage which is lower than in junctions PN of the lightly doped regions LDD, LDDTA.

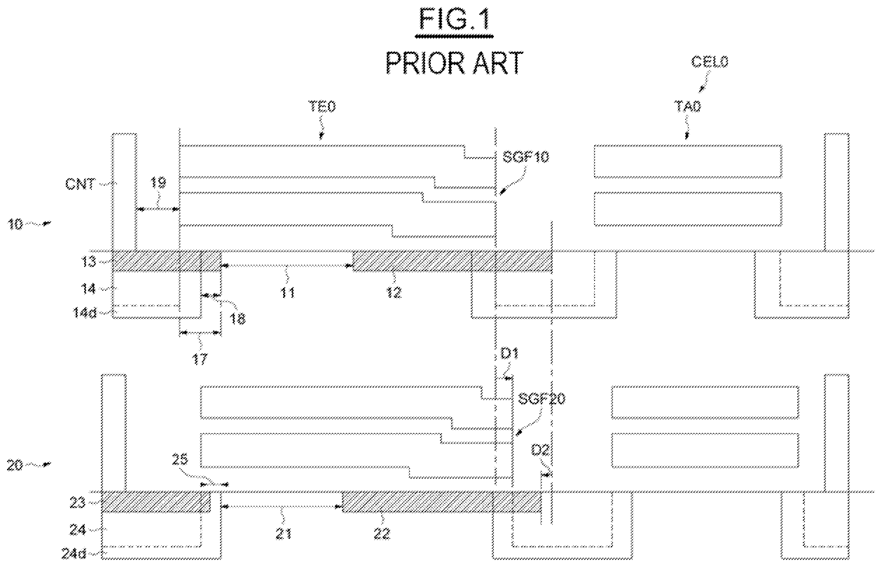

In other words, the conventional implantation of the source region 14-14d (FIG. 1) is not carried out, and the source region consists only of the second capacitive implant region 105. This allows preventing the source region from diffusing inside the channel in the direction of the drain, and thus avoiding a reduction in the length of the channel caused by misalignment.

Furthermore, the absence of diffusion inside the channel allows reducing the size of the cover 110 of the second capacitive implant region 105 under the gate SG, while keeping the benefit of the length of the channel 101 perfectly monitored between the first capacitive implant region 103 and the second capacitive implant region 105.

Reference is made in this regard to the representation of the memory cell CEL in the offset position 200.

The offset position 200 corresponds to a critical case in which the gate structure SG is positioned with an offset D1 towards the contact CNT of bit line BL, while the capacitive implant regions 203, 205 are positioned with an offset D2 towards the contact CNT of source line SL.

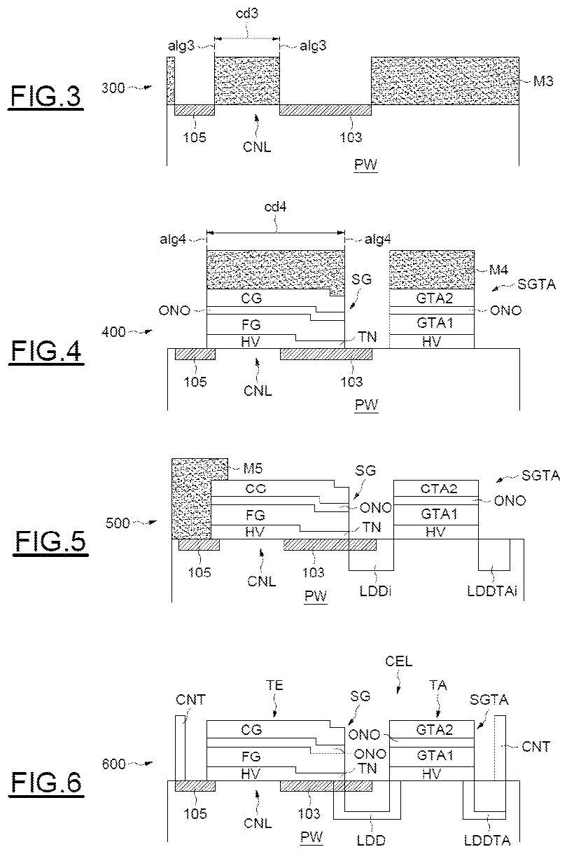

The offsets D1, D2 may result from variations in the alignment (usually “overlay”) of the masks used in the manufacturing processes. Indeed, as described below in relation to FIGS. 3 to 6, masking steps are used one after the other, and the position of each mask is aligned on a common reference, and not successively on top of each other in the order of use. Consequently, the offsets D1 and D2 can have opposite and decorrelated directions, that is to say, without the positions thereof being based on each other.

On the other hand, the relative offset between the gate structure SG and the second capacitive implant region 205 can also result from variation in the dimensions of the produced structures (usually “ΔCD” for the variation in the “Critical Dimension”).

Indeed, if the size of the gate structure SG and the size of the second capacitive implant region 205 are smaller, this contributes to move them away from each other (not represented).

However, for a normal operation of the state transistor TE, the channel region CNL should be completely covered by the gate structure SG.

It is considered that the offsets D1 and D2 of the position 200 correspond to a maximum tolerance of said variations in alignment and said variations in dimension “ΔCD” of the manufacturing process of the memory cell CEL.

Consequently, the portion 110 of the second capacitive implant region 105, which is located under the SG gate structure, can be minimized taking into account only these tolerances.

Thus, in the nominal position 100, the size 110 of a portion of the second capacitive implant region 105 covered by the gate structure SG, is advantageously provided to only compensate for the tolerance of variations D1 in the dimensions and alignment of the gate structure SG, and tolerance of variations D2 in the dimensions and alignment of the capacitive implant regions 103, 105.

The term “nominal position” means the position of an embodiment having no misalignment, that is to say also the position provided in the architectural drawings of the integrated circuit.

In particular, the size 110 does not need to take into account the extent of the diffusion of a conventional lightly doped source region.

This corresponds to an optimal compromise between the absence of risk caused by a misalignment, and the reduction in size of the memory cell.

Indeed, in order to minimize the size 110 of the portion of the second capacitive implant region 105 covered by the gate SG, the size of the gate structure SG (in the direction of the channel CNL) can be reduced by a measurement 120, for an unchanged channel length 101.

It is thus possible to offset the contact pillar CNT of source line SL by the measure 120 towards the gate structure SG, while preserving the safety space 119 between the gates FG, CG and the contact pillar CNT.

The positions of the contact CNT of source line SL and of the gate structure SG of the memory cell CEL0 previously described in relation to FIG. 1 are represented in dotted lines, to illustrate the dimension of the measurement 120.

The measurement 120 may for example be substantially equal to 0.04 μm (micrometer). This may represent about 3% of reduction in the total size of the memory cell CEL (in the direction of the channel, that is to say the size of the memory cell CEL between the contact CNT of source line SL and the contact CNT of bit line BL).

If the memory cells CEL of the memory plane represent 70% of the size of the complete integrated circuit CI, then the gain in size can represent between 2% and 2.5% of the total size of the integrated circuit CI. This amounts to a considerable production gain of 2% to 2.5% more integrated circuits CI per wafer.

FIGS. 3 to 6 illustrate steps and results of manufacturing steps of the memory cell CEL previously described in relation to FIG. 2.

FIG. 3 illustrates a step 300 for implanting, in a semiconductor well PW, capacitive implant regions 103, 105. The first capacitive implant region 103 is positioned on a drain side of the future state transistor and the second capacitive implant region 105 is positioned on a source side of the future state transistor.

In order to position the capacitive implant regions 103, 105, a temporary mask M3 is used, typically formed of photosensitive resin, lithographed so as to have openings at the regions to be implanted, and to cover the regions which are not intended to be implanted.

The implantation areas 300 of the first capacitive implant region 103 and the second capacitive implant region 105 allow delimiting, on either side, the channel region CNL in the well PW.

The formation of the mask M3 by photolithography uses an optical element, also called mask, aligned with a reference frame common to the other used optical masks in the method.

The dimensions cd3 of the elements formed in the mask M3 can vary within a certain tolerance depending on the techniques employed in the method, as well as the alignment alg3 of the elements formed in the mask M3.

The mask M3 is removed after the implantation 300, typically by chemical dissolution.

FIG. 4 illustrates a final step in the formation 400 of the gate structure SG of the future state transistor and the gate structure SGTA of the future access transistor.

The formation of the gate structures SG, SGTA is advantageously common for the state transistor and the access transistor.

A dielectric layer (typically silicon oxide) is first formed over the entire front face of the well PW, for example a silicon oxide growth with a thickness of substantially 14 nm. Then this dielectric layer is removed by etching at the future tunnel window TN of the state transistor. A second dielectric layer is formed over the entire front face of the well PW, so as to obtain a tunnel thickness TN of 7 to 9 nm in the tunnel window, and a cumulative thickness called high-voltage thickness HV of substantially 22 nm (from 21 to 23 nm) everywhere else.

The tunnel window TN is positioned opposite to the first capacitive implant region 103. The positioning of the first capacitive implant region 103 and the tunnel window TN are provided such that a major portion, which is substantially centered, of the first capacitive implant region 103 is located opposite to the tunnel window TN.

A first conductive layer FG-GTA1, for example made of polycrystalline silicon, is formed on the dielectric layer HV-TN thus obtained.

An inter-gate dielectric layer ONO, for example an oxide-nitride-silicon oxide superposition, is formed on the first conductive layer FG-GTA1.

A second conductive layer CG-GTA2, for example made of polycrystalline silicon, is formed on the inter-gate dielectric layer ONO.

A temporary resin mask M4 is formed, also by photolithography, on the superposition of gate structures so as to cover the locations of the future gate regions before etching.

The formation of the mask M4 also uses an optical mask aligned with the reference frame common to the other optical masks used in the method.

Again, the dimensions cd4 of the elements formed in the mask M4 may vary within a certain tolerance depending on the techniques employed in the method, as well as the alignment alg4 of the elements formed in the mask M4.

The mask M4 is positioned such that a major portion of the first capacitive implant region 103 is located under the masked portion of the gate structure SG, and that a major portion of the second capacitive implant region 105 is located outside the masked portion of the gate structure SG.

The mask M4 is also positioned such that a minor portion 110 (FIG. 2) of the second capacitive implant region 105 is located under the masked portion of the gate structure SG, the channel region CNL thus being completely covered by the masked portion of the gate structure SG.

The minor portion 110 (FIG. 2) of the second capacitive implant region 105 is in particular provided, in a nominal position, to compensate for a tolerance of variations in the dimensions cd4 and alignment alg4 of the mask M4 defining the final position of the gate structure SG, and a tolerance of variations in the dimensions cd4 and alignment alg3 of the mask M3 defining the final position of the second capacitive implant region 105.

An etching is then carried out in the uncovered portions of the mask M4, so as to remove the stack of the dielectric and conductive layers HV-TN, FG-GTA1, ONO, CG-GTA2, up to the front face of the well PW.

The etching can for example be of the dry etching type, such as plasma or reactive ion etching (usually “RIE”).

The mask M4 is removed after the etching, typically by chemical dissolution.

The gate structure SG of the state transistor has thus been formed, comprising a dielectric layer HV-TN provided with a tunnel window facing the first capacitive implant region 103, a floating gate FG, and a control gate CG separated from the floating gate FG by an inter-gate dielectric layer ONO; as well as the gate structure SGTA of the access transistor, in which the two conductive gate regions GTA1, GTA2 are electrically connected so as to have a single gate structure.

FIG. 5 illustrates a formation 500 of the lightly doped regions LDDi, LDDTAi.

The formation 500 first comprises producing a temporary mask M5, also made of photolithographed resin, on the semiconductor substrate PW on the source side of the future state transistor.

The mask M5 will prevent weakly concentrated dopants from being implanted in the future source region of the state transistor, at the second capacitive implant region 105.

The position of the mask M5 is not critical, since the portion masked by the mask M5 does not define a dimension of an element of the memory cell CEL. The mask M5 can thus be formed so as to protrude beyond the region that it protects, and is not sensitive to variations in shape and alignment.

The implantation of low concentration dopants LDDi, LDDTAi is self-aligned on the gate structure SG of the state transistor, and on the gate structure SGTA of the access transistor.

The self-alignment corresponds to the use of the already formed gate structures SG, SGTA as a mask against the implantation. This allows, in a manner which is conventional and known per se, positioning the conduction regions of the transistors without the risk of misalignment between different masks.

A lightly doped region LDDi has thus been implanted in the future drain region of the state transistor, as well as in the future source and drain regions of the access transistor, on either side of the gate structure SGTA of the access transistor.

The lightly doped region LDDi implanted between the gate structure SG of the state transistor and the gate structure SGTA of the access transistor is common to the future drain region of the state transistor and to the future source region of the access transistor.

It is thus proposed to prevent the self-aligned implantation of the lightly doped region in the source region of the state transistor, by means of a mask during this implantation. This allows, as previously expressed, avoiding the risk of reducing the length of the channel while reducing the size of the memory cells.

Furthermore, the introduction of the mask M5 during the implantation step 500 of the lightly doped regions does not introduce an additional step in itself, but a simple change of a typically already existing mask to carry out the self-aligned implantation in the uncovered portions of this mask. In the usual conventional methods, all or almost all the memory plane is uncovered, while the peripheral control circuit is predominantly covered by the mask.

FIG. 6 illustrates the result of a step 600 of forming of metal contact pillars CNT, and of diffusing the lightly doped regions LDDi, LDDTAi which are implanted in step 500.

After diffusion, the access transistor TA includes a lightly doped drain region LDDTA, and a lightly doped source region LDD.

The state transistor TE includes a drain region including the lightly doped region LDD of the source of the access transistor TA, and a drain extension consisting of the first capacitive implant region 103. The source region of the state transistor TE is exclusively composed of the second capacitive implant region 105.

The contacts CNT allow electrically connecting the source region 105 of the state transistor TE to a source line SL, and the drain region LDDTA of the access transistor to a bit line BL.

An integrated circuit may be summarized as including a non-volatile memory of the electrically erasable and programmable type including memory cells (CEL), each memory cell (CEL) having a state transistor (TE) including a gate structure (SG) including a control gate (CG) and a floating gate (FG) disposed on a face of a semiconductor well (PW), as well as a source region and a drain region in the semiconductor well (PW), the drain region including a first capacitive implant region (103) positioned predominantly under the gate structure (SG) and a lightly doped region (LDD) positioned predominantly outside the gate structure (SG), the source region including a second capacitive implant region (105) positioned predominantly outside the gate structure (SG), the source region not including a lightly doped region.

In a nominal position (100) of the gate structure (SG) and the second capacitive implant region (105), a minor portion (110) of the second capacitive implant region (105) may be positioned under the gate structure (SG), said minor portion (110) having the minimum size allowing compensating for a tolerance of variations (D1) in the dimensions and alignment of the gate structure (SG), and a tolerance of variations (D2) in the dimensions and alignment of the capacitive implant regions (103, 105).

A channel region of the well (CNL) located under the gate structure (SG), may be delimited on either side by the first capacitive implant region (103) and by the second capacitive implant region (105).

The gate structure may include a dielectric layer (HV, TN) between the floating gate (FG) and the semiconductor well (PW), the dielectric layer having a first thickness (HV) and a second thickness (TN) less than the first thickness (HV), the channel region (CNL) being positioned opposite to the first thickness (HV), and the first capacitive implant region (103) being positioned predominantly opposite to the second thickness (TN).

Each memory cell (CEL) further having an access transistor (TA) may include a gate structure (SGTA) disposed on the face of the semiconductor well (PW), as well as a source region (LDD) and a drain region (LDDTA) in the semiconductor well, the drain region of the access transistor may include a lightly doped region (LDDTA) positioned predominantly outside the gate structure of the access transistor (SGTA), and the source region of the access transistor may include the same lightly doped region (LDD) as the drain region of the state transistor (TE), positioned predominantly outside the structure gate of the access transistor (SGTA).

A method for manufacturing a non-volatile memory of the electrically erasable and programmable type of an integrated circuit, may be summarized as including a formation of state transistors (TE) of memory cells (CEL) including, for each memory cell (CEL) an implantation (300), in a semiconductor well (PW), of a first capacitive implant region (103) positioned on a drain side of the state transistor and of a second capacitive implant region (105) positioned on a source side of the state transistor; a formation (400) of a gate structure (SG) on a face of the semiconductor well (PW) including a control gate (CG) and a floating gate (FG), positioned such that a major portion of the first capacitive implant region (103) is located under the gate structure (SG) and that a major portion of the second capacitive implant region (105) is located outside the gate structure (SG); a formation (500) of a lightly doped region, including a formation of a temporary mask (M5) on the semiconductor substrate (PW) on the source side of the state transistor (TE), and an implantation of dopants (LDDi) self-aligned on the gate structure (SG) on the drain side of the state transistor (TE).

In a nominal position of the positioning of the implantation of the capacitive implant regions (300) and the positioning of the formation of the gate structure (400), a minor portion of the second capacitive implant region (105) may be positioned under the gate structure (SG), said minor portion having the minimum size allowing compensating for a tolerance of variations in the dimensions (cd4) and alignment (alg4) of the gate structure (SG), and a tolerance of variations in the dimensions (cd3) and alignment (alg3) of the capacitive implant regions (103, 105).

The implantation (300) of the first capacitive implant region (103) and the implantation (300) of the second capacitive implant region (105) delimit on either side a channel region of the well (CNL), and the formation of the gate structure (400) may be positioned such that the channel region (CNL) may be located under the gate structure (SG).

The formation of the gate structure (400) may include a formation of a dielectric layer (HV, TN) between the floating gate (FG) and the semiconductor well (PW), including a formation of a first thickness of the dielectric layer (HV) and a second thickness of the dielectric layer (TN) which may be less than the first thickness (HV), the formation of the gate structure (SG) being positioned such that the channel region (CNL) may be located opposite to the first thickness (HV), and that the first capacitive implant region (103) may be positioned predominantly opposite to the second thickness (TN).

The method may further include a formation of access transistors (TA) for each memory cell (CEL), wherein said formation (400) of the gate structure (SG) of the state transistor (TE) may further include a formation of a gate structure (SGTA) of the access transistor (TA); said formation of the lightly doped region (500), may include said implantation of dopants (LDDTAi) further self-aligned on the gate structure of the access transistor (SGTA) forming a lightly doped region (LDDTA) of a drain of the access transistor (TA) and a lightly doped region (LDD) of a source of the access transistor (TA) which may be common to the lightly doped region (LDD) of the drain of the state transistor (TE).

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated circuit, comprising:
a non-volatile memory of the electrically erasable and programmable type including memory cells, each memory cell including:
a state transistor including a gate structure including a control gate and a floating gate disposed on a face of a semiconductor well; and
a source region and a drain region in the semiconductor well, the drain region including a first capacitive implant region positioned predominantly under the gate structure and a lightly doped region positioned predominantly outside the gate structure, the source region including a second capacitive implant region positioned predominantly outside the gate structure, the source region not including a lightly doped region.

2. The integrated circuit according to claim 1, wherein, in a nominal position of the gate structure and the second capacitive implant region, a minor portion of the second capacitive implant region is positioned under the gate structure, the minor portion having a substantially minimum size allowing compensating for a tolerance of variations in the dimensions and alignment of the gate structure, and a tolerance of variations in the dimensions and alignment of the capacitive implant regions.

3. The integrated circuit according to claim 1, wherein a channel region of the well located under the gate structure, is delimited on either side by the first capacitive implant region and by the second capacitive implant region.

4. The integrated circuit according to claim 3, wherein the gate structure includes a dielectric layer between the floating gate and the semiconductor well, the dielectric layer having a first thickness and a second thickness less than the first thickness, the channel region being positioned opposite to the first thickness, and the first capacitive implant region being positioned predominantly opposite to the second thickness.

5. The integrated circuit according to claim 1, each memory cell further including:
an access transistor including a gate structure disposed on the face of the semiconductor well, and a source region and a drain region in the semiconductor well, the drain region of the access transistor including a lightly doped region positioned predominantly outside the gate structure of the access transistor, and the source region of the access transistor including the same lightly doped region as the drain region of the state transistor, positioned predominantly outside the structure gate of the access transistor.

6. A device, comprising:
a semiconductor substrate having a semiconductor well;
a first transistor including a gate structure, the gate structure including:
a floating gate the semiconductor well, the floating gate including a first portion spaced apart from a surface of the well by a first distance and a second portion spaced apart from the surface of the well by a second distance, the first distance being greater than the second distance;
a control gate on the floating gate, the floating gate disposed between the semiconductor well and the control gate;
a source region and a drain region in the semiconductor well, the drain region including a first capacitive implant region extending under the gate structure and a lightly doped region extending laterally outward beyond the gate structure, the source region including a second capacitive implant region extending laterally outward beyond the gate structure, the source region not including a lightly doped region.

7. The device according to claim 6, wherein, in a nominal position of the gate structure and the second capacitive implant region, a minor portion of the second capacitive implant region is positioned under the gate structure, the minor portion having a substantially minimum size allowing compensating for a tolerance of variations in the dimensions and alignment of the gate structure, and a tolerance of variations in the dimensions and alignment of the capacitive implant regions.

8. The device according to claim 6, wherein a channel region of the well located under the gate structure, is delimited on either side by the first capacitive implant region and by the second capacitive implant region.

9. The device according to claim 8, wherein the gate structure includes a dielectric layer between the floating gate and the semiconductor well, the dielectric layer having a first thickness and a second thickness less than the first thickness, the channel region being positioned opposite to the first thickness, and the first capacitive implant region being positioned predominantly opposite to the second thickness.

10. The device according to claim 6, further comprising:
an access transistor including a gate structure disposed on the semiconductor well, and a source region and a drain region in the semiconductor well, the drain region of the access transistor including a lightly doped region extending laterally outward beyond the gate structure of the access transistor, and the source region of the access transistor including the same lightly doped region as the drain region of the state transistor, the source region extending laterally outward beyond the structure gate of the access transistor.

11. A method for manufacturing a non-volatile memory of the electrically erasable and programmable type of an integrated circuit, comprising:
forming state transistors of memory cells including, for each memory cell:
forming, in a semiconductor well, a first capacitive implant region positioned on a drain side of the state transistor and a second capacitive implant region positioned on a source side of the state transistor;
forming a gate structure on a face of the semiconductor well including a control gate and a floating gate, positioned such that a major portion of the first capacitive implant region is located under the gate structure and a major portion of the second capacitive implant region is located outside the gate structure; and
forming a lightly doped region, including forming a temporary mask on the semiconductor substrate on the source side of the state transistor, and implanting dopants self-aligned on the gate structure on the drain side of the state transistor.

12. The method according to claim 11, wherein in a nominal position of the positioning of the implantation of the capacitive implant regions and the positioning of the formation of the gate structure, a minor portion of the second capacitive implant region is positioned under the gate structure, the minor portion having the minimum size allowing compensating for a tolerance of variations in the dimensions and alignment of the gate structure, and a tolerance of variations in the dimensions and alignment of the capacitive implant regions.

13. The method according to claim 11, wherein the first capacitive implant region and the second capacitive implant region delimit on either side a channel region of the well, and the gate structure is positioned such that the channel region is located under the gate structure.

14. The method according to claim 13, wherein the forming the gate structure includes:
forming a dielectric layer between the floating gate and the semiconductor well, the dielectric layer having a first thickness and a second thickness which is less than the first thickness, the gate structure being positioned such that the channel region is located opposite to the first thickness, and that the first capacitive implant region is positioned predominantly opposite to the second thickness.

15. The method according to claim 11, further comprising forming access transistors for each memory cell, wherein:
the forming the gate structure of the state transistor further forming a gate structure of the access transistor; and
the forming the lightly doped region includes implanting the dopants self-aligned on the gate structure of the access transistor forming a lightly doped region of a drain of the access transistor and a lightly doped region of a source of the access transistor which is common to the lightly doped region of the drain of the state transistor.
